(19) United States
(12) Patent Application Publication
(10) Pub. No.: US 2006/0286292 A1
(43) Pub. Date: Dec. 21, 2006

(54) Fabricating thin-film magnetic recording heads using multi-layer DLC-type protective coatings

(75) Inventors: Ming Jiang, San Jose, CA (US); Ning Shi, San Jose, CA (US); Sue Siyang Zhang, Saratoga, CA (US); Yi Zheng, San Ramon, CA (US)

Correspondence Address: DUFT BORNSEN & FISHMAN, LLP, 1526 SPRUCE STREET, SUITE 302, BOULDER, CO, 80302, US

(73) Assignee: HITACHI GLOBAL STORAGE TECHNOLOGIES NETHERLANDS B.V.

(21) Appl. No.: 11/151,626

(22) Filed: Jun. 13, 2005

(51) Int. Cl. B05D 5/12; C23C 16/00

(52) U.S. Cl. 427/127; 427/249.7; 427/402

(57) ABSTRACT

An improved method of fabricating thin-film magnetic recording heads is disclosed. For the method, one or more layers for a feature (such as a read element, a write element, etc) are deposited and patterned. A layer of adhesion material is then deposited on the layers of the feature. The adhesion material provides better adhesion to a Diamond-Like Carbon (DLC) layer and to the underlying feature surface, such as monolithic Silicon (Si) or Titanium (Ti). A layer of DLC material is then deposited on the layer of adhesion material. The steps of depositing the layer of adhesion material and the layer of DLC material are repeated more than one time. Thus, more than one set of alternating layers of adhesion material and DLC material are deposited on the layers of the feature to form a multi-layer protective coating on the feature.

### BACKGROUND OF THE INVENTION

1. Field of the Invention

The invention is related to the field of magnetic disk drive systems, and in particular, to methods of fabricating thin-film magnetic recording heads of magnetic disk drive systems using multi-layer Diamond-Like Carbon (DLC) protective coatings that protect feature layers.

2. Statement of the Problem

Many computer systems use magnetic disk drives for mass storage of information. Magnetic disk drives typically include one or more thin-film magnetic recording heads (sometimes referred to as sliders) that include read elements, write elements, and other electrical elements. The most common type of read elements are magnetoresistive (MR) read elements, such as Giant MR (GMR) read elements or Magnetic Tunnel Junction (MTJ) read elements.

Thin-film magnetic recording heads are typically fabricated on a substrate wafer. Materials are deposited onto a ceramic substrate to create an array of thin-film magnetic recording heads. A device-on-substrate assembly like this is commonly referred to as a device wafer by those skilled in the art. Each thin-film magnetic recording head includes multiple layers of materials to form critical features of the thin-film magnetic recording head, such as the read and write elements. The materials also form features like heaters, magnetic shields, insulators, electrical traces, and electrical pads.

Fabrication of thin-film magnetic recording heads involves many processes of depositing materials and subsequent removal of unwanted portions to shape the features of the thin-film magnetic recording head in a desired manner. One of the processes used in the fabrication of thin-film magnetic recording heads is a Chemical/Mechanical Polishing (CMP) lift-off process. A CMP process uses a combination of a chemical reaction and mechanical abrasion to remove materials at their respective designed rate. A CMP lift-off process is designed to mate with the device wafer to remove by CMP one or more layers of material in the designated areas. For functional feature layers exposed to the mechanical/chemical process, the CMP lift-off process can functionally damage these features. Therefore, a temporary protective coating is deposited over the feature that is mechanically hard, wear resistant, and chemically inert. The protective coating protects the feature during the CMP lift-off process, and can later be removed.

The protective coating typically used is comprised of a Diamond-Like Carbon (DLC) material. A single layer of Silicon (Si) of a thickness between 10-50 Å is first deposited on the feature as an adhesion layer. A single layer of DLC of a thickness between 50-300 Å is then deposited in-situ on the Si layer. These two layers form a single layer protective coating for the feature.

One problem facing thin-film magnetic recording head fabricators is that, while DLC is mechanically hard, it also has a highly compressive intrinsic film stress. This intrinsic property of DLC may cause de-lamination of the protective coating from the feature layers it is to protect. The internal compressive film stress of DLC induces interfacial misfit shear stress at the film interface, causing film de-lamination. This phenomenon is more prominent at feature corners and ends where dissimilar materials meet. When this de-lamination occurs, features may be damaged during processes such as CMP lift-off. Therefore, recording head fabricators need improved ways of protecting functional features during a CMP lift-off process or other processes.

One proposed method of improving DLC tribological properties is to decrease the H-content of the DLC layer while still maintaining the SP3 diamond-like bonding structure. This generally results in increased hardness, as Hydrogen is a known SP3 bond promoter, but its bond strength is not as strong as a C-C diamond SP3 bond. Another proposed method is to increase the film wear-through budget by increasing the thickness of the DLC layer. Unfortunately, both methods significantly increase the film interfacial shear misfit. An increased film interfacial misfit is likely to result in the protective coating de-laminating from the protected feature. Even though the wear-through budget may be increased, the overall protection provided by the protective coating may be ineffective or may even degrade. Another method is needed that provides sufficient wear-resistance but does not significantly increase the film stress of the DLC.

### SUMMARY OF THE SOLUTION

The invention solves the above and other related problems with methods of fabricating thin-film magnetic recording heads by using multiple layers of DLC in the protective coating of a feature. The multi-layer (DLC) protective coating advantageously has reduced film stress and friction as compared to the single (DLC) layer protective coating. Therefore, the multi-layer protective coating advantageously has a reduced chance of de-laminating from the feature through reduction of intrinsic interfacial shear misfit and reduction of friction during CMP. At the same time, the multi-layer protective coating has a substantially similar mechanical hardness as a single layer protective coating of a similar thickness.

One embodiment of the invention comprises an improved method of fabricating thin-film magnetic recording heads. For the method, one or more layers for a feature are deposited. A layer of adhesion material is subsequently deposited on the layers of the feature. The adhesion material provides better adhesion to the underlying feature surface and to the DLC subsequently deposited, promoting a coherent film stack adhering to the substrate features. The adhesion material may be both carbide-forming and oxide-forming, such as monolithic Silicon (Si) or Titanium (Ti). For this embodiment, the adhesion material comprises Silicon (Si), which advantageously provides a reduction of stress and friction without much hardness degradation in a Si-doped DLC. A layer of DLC material is then deposited in-situ on the layer of adhesion material. The DLC layer can be deposited from any known technique familiar to those skilled in the art. The steps of depositing the layer of adhesion material and depositing the layer of DLC material are repeated more than one time in-situ. Thus, more than one set of alternating layers of adhesion material and DLC material are deposited on the layers of the feature to form a multi-layer protective coating on the feature. The final stack of layers may have the same or similar thickness as the prior-art single layer protective coating. The multi-layer protective coating is more effective than a single layer protective coating with the same final thickness to protect the feature during processes, such as a CMP lift-off process. The multi-layer protective coating, having reduced film stress and friction, also allows for increased thickness of the protective coating to increase wear-through budget without the unwanted film de-lamination during CMP.

The invention may include other exemplary embodiments described below.

### DESCRIPTION OF THE DRAWINGS

The same reference number represents the same element on all drawings.

FIG. 1 illustrates a wafer of thin-film magnetic recording heads.

FIG. 2 illustrates a thin-film magnetic recording head.

FIGS. 3-8 illustrate an exemplary process of fabricating a read element for a single thin-film magnetic recording head.

FIGS. 9-13 illustrate an exemplary process of fabricating a write element for a single thin-film magnetic recording head.

FIG. 14 is a flow chart illustrating a method of fabricating thin-film magnetic recording heads in an exemplary embodiment of the invention.

FIG. 15 illustrates a protective coating generated by the method of FIG. 14 in an exemplary embodiment of the invention.

### DETAILED DESCRIPTION OF THE INVENTION

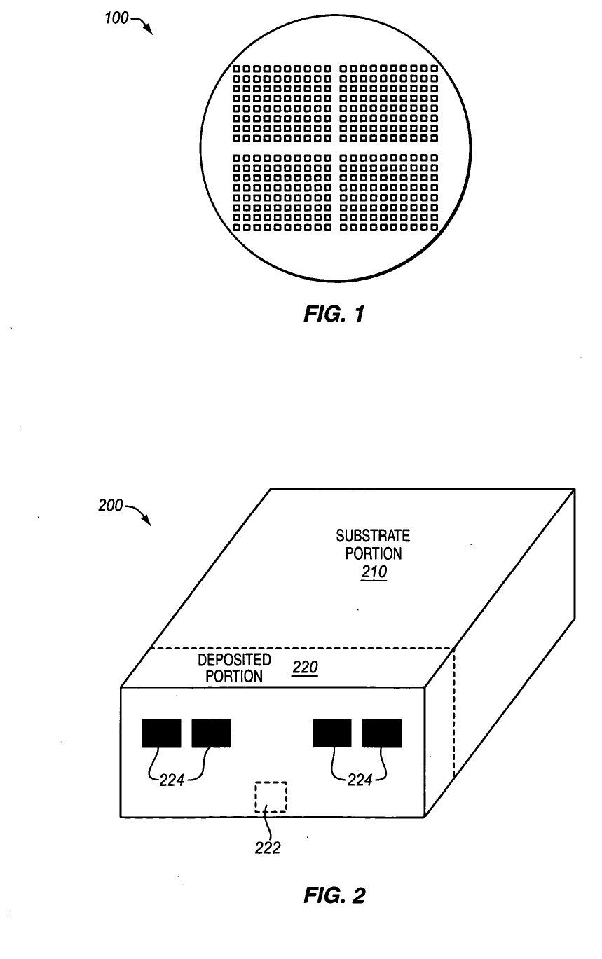

FIG. 1 illustrates a wafer 100 of thin-film magnetic recording heads. In fabrication of thin-film magnetic recording heads, wafer 100 is a substrate upon which layers of material are deposited to form an array of thin-film magnetic recording heads. The materials deposited on wafer 100 form critical features of the thin-film magnetic recording heads, such as the read and write elements. The materials also form features such as magnetic shields, insulators, electrical traces, and electrical pads. The thin-film magnetic recording heads, also known as sliders by those skilled in the art, are then cut out of the wafer 100.

FIG. 2 illustrates a thin-film magnetic recording head 200 cut out of the wafer 100. Thin-film magnetic recording head 200 includes a substrate portion 210, which comprised the wafer 100 before cutting the thin-film magnetic recording head 200 out of the wafer 100. Thin-film magnetic recording head 200 also includes a deposited portion 220 generated by the fabrication processes. The deposited portion 220 includes, for instance, read and write element 222 and electrical pads 224. The deposited portion 220 may include other features not shown in FIG. 2.

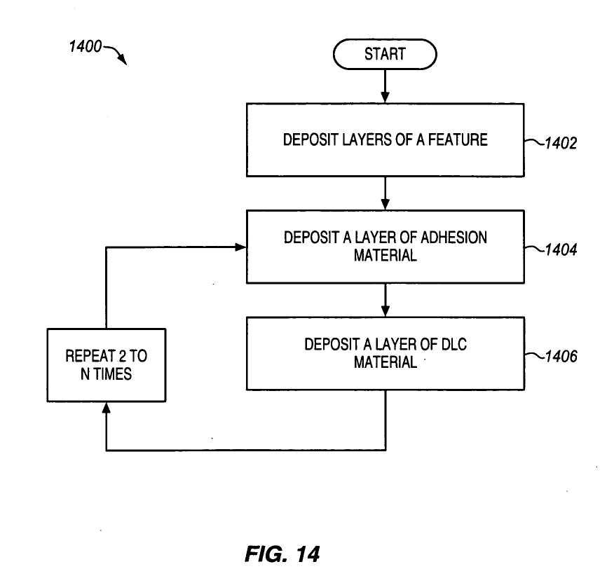

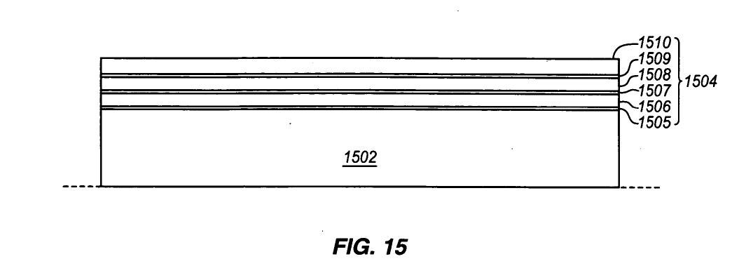

FIGS. 3-13 illustrate processes of fabricating a recording head, such as recording head 200. In the fabrication process, a prior art single (DLC) layer protective coating (protective coating 306) is used to protect a feature during the fabrication processes. Then an improved multi-layer protective coating is described in FIGS. 14-15. The multi-layer protective coating may be used in place of the single layer protective coating in the fabrication processes described in FIGS. 3 and 5-13.

FIGS. 3-8 illustrate an exemplary process of fabricating a read element for a single thin-film magnetic recording head. This process is described in order to show the function of a protective coating to protect a feature, such as the read element, during fabrication, including those with extreme feature size in future generation recording heads. Those skilled in the art will understand that numerous other processes are involved in fabricating thin-film magnetic recording heads that are not shown for the sake of brevity. Those skilled in the art will also understand that similar processes are performed for the other thin-film magnetic recording heads on the wafer 100. Other features of the thin-film magnetic recording head can be formed in a similar manner, such as write elements, heaters, etc.

FIG. 3 illustrates a substrate 302 upon which one or more layers of a thin-film read element 304 are deposited. The layers deposited for read element 304 are larger than are actually needed, so the excess material needs to be removed with a removal process, such as an etching process, a milling process, or some other process. To protect the portion of the read element 304 that is not to be removed, a protective coating 306 and a photo-resist 308 are deposited over that portion of the read element 304. The protective coating 306 is to protect the read element 304 during a subsequent Chemical/Mechanical Polishing (CMP) lift-off process. The photo-resist 308 defines what portion of the layers of read element 304 will be removed in the subsequent removal process.

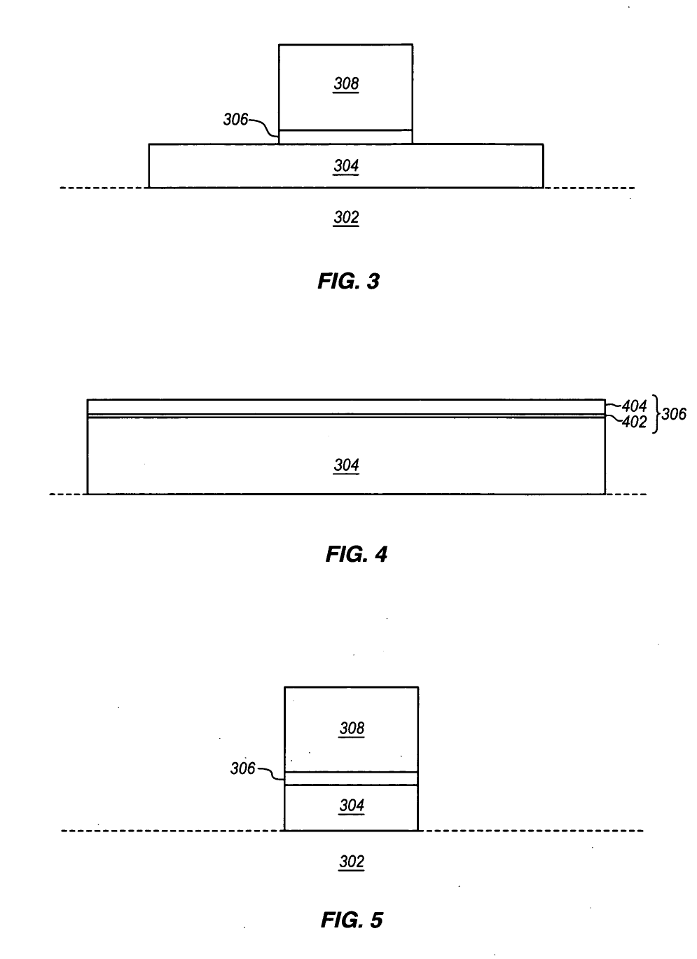

FIG. 4 illustrates the protective coating 306 typically used to protect features, such as read element 304. First, a single layer 402 of Silicon (Si) of a thickness between 10-50 Å is deposited on the portion of the read element 304 that is to be protected. The Si layer 402 acts as an adhesion layer. Next, a single layer 404 of Diamond-Like Carbon (DLC) of a thickness between 50-300 Å is deposited on the Si layer 402. These two layers 402, 404 form the protective coating 306. Because protective coating 306 includes a single DLC layer 404, this protective coating 306 is referred to as a single layer protective coating.

Problems exist in the prior art protective coating 306. While DLC is mechanically hard, it also has a highly compressive intrinsic film stress. This intrinsic property of DLC may cause de-lamination of the protective coating 306 from the feature layers it is to protect. Due to the internal compressive stress of DLC, the DLC layer 404 has tendency to reduce in size and volume, causing interfacial shear misfit. Such interfacial misfit induces film de-lamination along feature-film interface, especially at the feature corners and ends where dissimilar materials meet. If the DLC layer 404 and/or adhesion layer 402 do de-laminate, the DLC layer 404 will not protect the feature during the CMP lift-off process and the feature may be damaged.

In FIG. 3, a designated removal process, such as an etching process, a milling process, or some other process, is then performed to remove the excess material on the outer perimeter of the read element 304. FIG. 5 illustrates the layers after the removal process. The remaining portion of read element 304 is the portion protected by the protective coating 306 and the photo-resist 308.

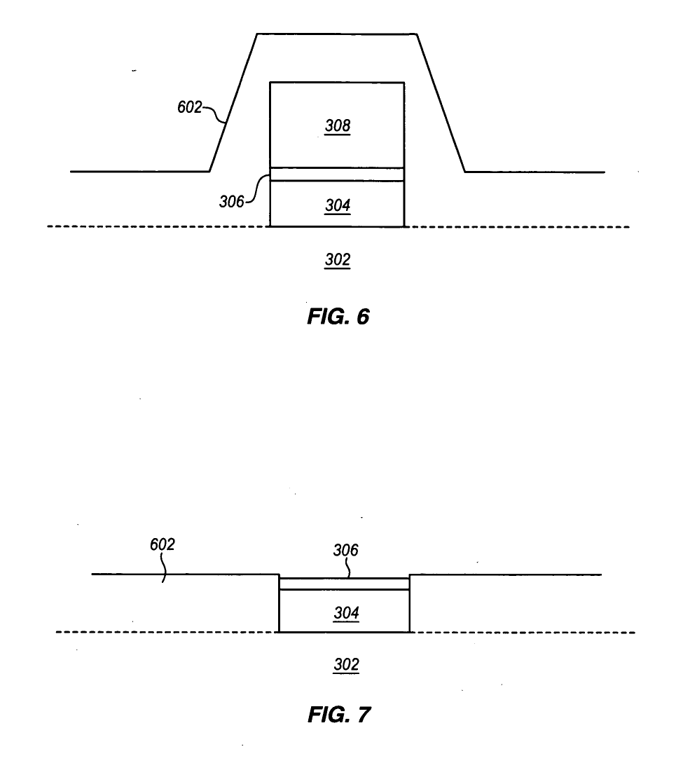

In FIG. 6, another layer 602 of material is deposited over and around read element 304, protective coating 306, and photo-resist 308. For instance, layer 602 may comprise materials forming Hard Bias and Lead. Excess material of layer 602 is deposited over and along the perimeter of read element 304, which needs to be removed with a CMP lift-off process. The CMP lift-off process is then performed to remove the excess material.

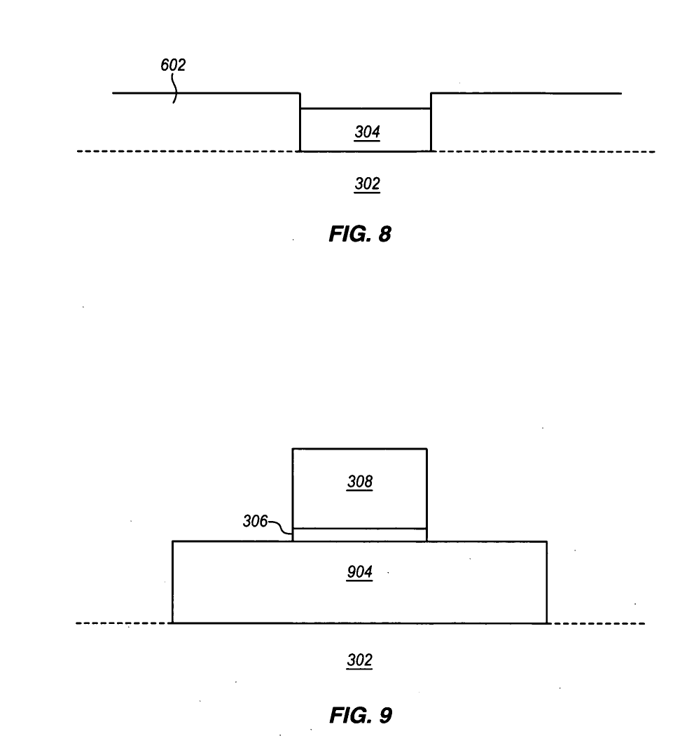

FIG. 7 illustrates the layers after the CMP lift-off process. The CMP lift-off process removes the excess material and the photo-resist 308. The protective coating 306 is intended to protect the read element 304 during the CMP lift-off process. The protective coating 306 acts as a stop layer for the process. After the CMP lift-off process is complete, the protective coating 306 may be removed with a reactive plasma ion etching process derived from precursor gases such as Hydrogen, Nitrogen, Oxygen, or mixtures of such. FIG. 8 illustrates the layers after the removal process. Other layers may then be added as desired in the fabrication process.

FIGS. 9-13 illustrate an exemplary process of fabricating a pole for a write element for a single thin-film magnetic recording head with extreme dimensions and morphologies including future generation write poles. This process is described in order to show the function of a protective coating to protect a feature, such as the pole for the write element, during fabrication. Those skilled in the art will understand that numerous other processes are involved in fabricating thin-film magnetic recording heads that are not shown for the sake of brevity.

FIG. 9 illustrates a substrate 302 upon which the material for a pole 904 for the write element is deposited. The material for the pole 904 that is deposited is actually more than is needed, so the excess material needs to be removed with a removal process, such as an etching process, a milling process, or some other process. To protect the portion of the pole 904 that is not to be removed, a protective coating 306 and a photo-resist 308 are deposited over that portion of the pole 904. The protective coating 306 is to protect the pole 904 during a subsequent CMP lift-off process. The photo-resist 308 defines what portion of the pole 904 will be removed in the subsequent removal process. The removal process, such as ion milling and other processes, is then performed to remove the excess material around pole 904.

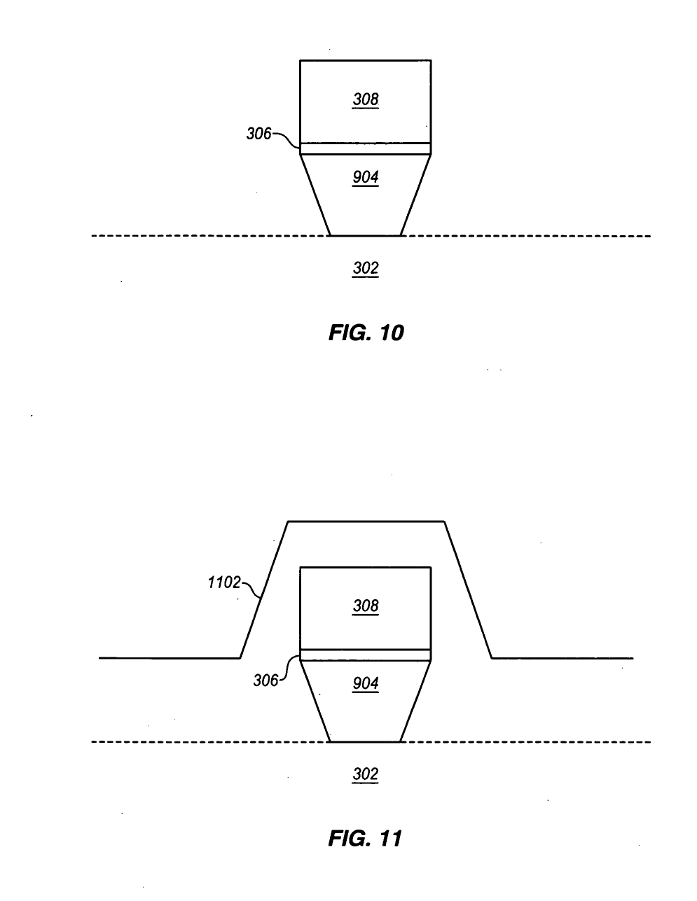

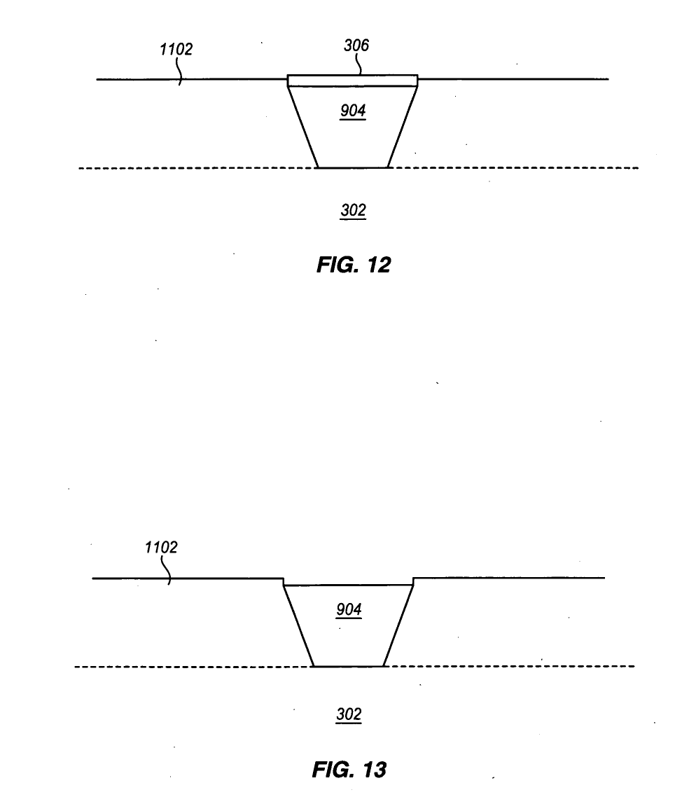

FIG. 10 illustrates the layers after the removal process. The remaining portion of the pole 904 is the portion protected by the protective coating 306 and the photo-resist 308. In FIG. 11, another layer 1102 of material is deposited over and around the pole 904, protective coating 306, and photo-resist 308. For instance, layer 1102 may comprise Al₂O₃ or other types of oxides, inter-metallic compounds or ionic ceramics, or other types of suitable hard and insulating materials. As before, excess material for layer 1102 is deposited over and along the perimeter of pole 904, so the excess material needs to be removed with the CMP lift-off process. The CMP lift-off process is then performed to remove the excess material. FIG. 12 illustrates the layers after the CMP lift-off process. The CMP lift-off process removes the excess material and the photo-resist 308. The protective coating 306 is intended to protect the pole 904 during the CMP lift-off process. The protective coating 306 acts as a stop layer for the process. After the CMP lift-off process is complete, the protective coating 306, if desired, may be removed with a plasma reactive ion etching process derived from precursor gases such as Hydrogen, Nitrogen, Oxygen, or mixtures of such. FIG. 13 illustrates the layers after the removal process. Other layers may then be added as desired in the fabrication process.

According to the invention, an improved protective coating may be used in place of protective coating 306 in fabricating thin-film magnetic recording heads. FIG. 14 is a flow chart illustrating a method 1400 of fabricating thin-film magnetic recording heads in an exemplary embodiment of the invention. Method 1400 may include numerous other steps for fabricating thin-film magnetic recording heads that are not shown in FIG. 14 for the sake of brevity.

In step 1402, one or more layers for a feature are deposited. A feature refers to any critical element in a thin-film magnetic recording head, such as a read element, a write element, a heater, etc, that needs to be protected with a protective coating during fabrication.

In step 1404, a layer of adhesion material is deposited on the layers of the feature. The adhesion material provides better adhesion to the underlying feature surface and a DLC layer to be subsequently deposited. Before deposition, as known to those skilled in the art, wafers with device features fully or partially made (from step 1402) maybe sputter-etched or a vacuum plasma process may be performed to remove air-born contamination for better adhesion. The adhesion material may be both carbide-forming and oxide-forming, such as monolithic Silicon (Si) or Titanium (Ti). For this embodiment, the adhesion material comprises Silicon (Si), which advantageously provides a reduction of stress and friction without much hardness degradation in a Si-doped DLC.

In step 1406, a layer of DLC material is deposited in-situ on the layer of adhesion material. The DLC layer can be made from any known technique familiar to those skilled in the art. The layer of adhesion material and the layer of DLC material are at least deposited on the portion of the feature that is to be protected in subsequent processing steps.

Steps 1404 and 1406 are then repeated more than one time so that more than one set of alternating layers of adhesion material and DLC material are deposited on the layers of the feature to form a multi-layer protective coating on the feature.

The repeat of steps 1404 and 1406 is to maximize Si-DLC inter-diffusion at the Si-DLC interface. The repeat of 1404 and 1406 creates multiple such interfaces with decreased interlayer spacing. DLC doped with Si is known to promote the SP3 bond while relaxing film stress. Consequently, individual layer thickness and hence the number of times steps 1404 and 1406 are repeated depends on the following factors. One factor is the thickness ratio between DLC to Si. The DLC to Si thickness ratio may range from about 3:1 to about 2:1. The DLC to Si thickness ratio is optimal at about 5:2 to maximize the effect of Si inter-diffusion without excessive repeats for a certain total thickness. If the thickness ratio is outside of the prescribed range, enhanced wear protection is still expected. With these ratios, the combined thickness of the adhesion material and the DLC material may be between about 50 Å and 150 Å. Another factor is the overall thickness of the protective coating. The number of times steps 1404 and 1406 are repeated is determined by the total thickness desired for the protective coating, which is commensurate with CMP process parameters. Total thickness can be readily determined by those skilled in the art.

FIG. 15 illustrates the multi-layer protective coating generated by method 1400 in an exemplary embodiment of the invention. In FIG. 15, a protective coating 1504 is deposited on a feature 1502. For the protective coating 1504 generated by method 1400, steps 1404 and 1406 are repeated three times so that there are three sets of alternating adhesion/DLC stacks.

According to method 1400, a first layer 1505 of adhesion material is deposited on the feature 1502, and a first layer 1506 of DLC material is deposited on the first layer 1505 of adhesion material. Next, a second layer 1507 of adhesion material is deposited on the first layer 1506 of DLC material, and a second layer 1508 of DLC material is deposited on the second layer 1507 of adhesion material. Next, a third layer 1509 of adhesion material is deposited on the second layer 1508 of DLC material, and a third layer 1510 of DLC material is deposited on the third layer 1509 of adhesion material.

The fabrication processes described in FIGS. 3 and 5-8, in FIGS. 9-13, and other fabrication processes can be performed with the protective coating 1504 according to the invention instead of protective coating 306 (see FIG. 4). The multi-layer protective coating 1504 of the invention provides increased protection to features of thin-film magnetic recording heads as compared to conventional single layer protective coatings 306. The multi-layer protective coating has reduced film stress and friction as compared to the single layer protective coating. Therefore, the multi-layer protective coating advantageously has a reduced chance of de-laminating from the feature. At the same time, the multi-layer protective coating has a substantially similar mechanical hardness as a single layer protective coating of a similar thickness, ensuring similar film wear-through protection.

After CMP lift-off, the protective coating 1504 is removed with conventional processes, such as reactive ion etching (RIE), ion milling, or some other process. The process required is readily available to those skilled in the art though may somewhat different from that of the single layer process.

The following describes why the multi-layer protective coating provides the advantages described above. First, the multi-layer protective coating provides increased Si—C inter-diffusion. DLC is a high energy deposition process that produces high film stresses and high hardness. A typical hydrogenated DLC layer usually has about 20+GPa of hardness and 2 to 3 GPa of compressive film residual stress. Depositing Si as an adhesion layer allows Si to form bonds to both the substrate (e.g., the feature) and the DLC layer, promoting film adhesion. As an added benefit, the Si and DLC form Si—C bonds, which have unique properties. These properties of Si-doped DLC significantly lower the film stress and improve the friction coefficient without a major compromise in film hardness.

The single layer Si-DLC provides these improvements, such as increased adhesion between DLC to Si and Si to feature layer, and reduction in film stress as compared with DLC intrinsic properties, but only locally at the DLC/substrate interface. The film stresses still build-up in the majority of the DLC layer apart from the DLC/Si/substrate interface. By inserting the Si layer between individual and thinner DLC layers, the number of Si-DLC interfaces is increased. Si—C inter-diffusion is therefore greatly enhanced. By increasing the Si—C inter-diffusion, the multi-layer protective coating has lower stress and a lower friction coefficient without significantly reducing Diamond-like bonding (SP3).

Such effect may also be achieved by co-depostion of Si and DLC instead of multi-layer repeats as described herein. Therefore, by teaching the principles of wear-resistance enhancement, those skilled in art may also practice other deposition techniques such as Si/DLC co-deposition to achieve greater Si-DLC inter-diffusion. In the co-deposition scenario, the Si material and the DLC material are deposited at the same time or substantially simultaneous to form a protective coating on a feature.

Another reason why the multi-layer protective coating provides enhanced protection is that the Si—C inter-diffusion reduces the film Stress Intensity Factor (SIF) of the protective coating. A single, thick DLC layer allows transverse cracks (perpendicular to film surface) to go deeper into the DLC layer before reaching the tougher Si—C interface. A deeper/larger crack gives rise to a higher SIF. A higher SIF usually translates into more damage in the event of mechanical abrasion, such as from the CMP lift-off process. By limiting interlayer thickness of the DLC layers, crack length is restricted to a maximum of interlayer thickness. Because SIF is a macroscopic and continuum attribute that is expected to work well beyond the microcosm of diffusion, it is then expected that beyond the 150 Å interlayer spacing, the multi-layer protective coating is still more robust than a single layer protective coating, as is commonly known as “composite materials”.

A multi-layer protective coating was tested against a single layer protective coating with a Pin-on-Disk wear test. The multi-layer protective coating was comprised of three Si layers (20 Å) and three DLC layers (100 Å). The single layer protective coating was comprised of a single Si layer (60 Å) and a single DLC layer (300 Å). Table 1 illustrates the results of the test.

TABLE 1

| | SLIDING | | | |
|---|---|---|---|---|
| | DISTANCE | NUMBER OF | | |
| | TO FAILURE | LAPS TO | MEAN μ BEFORE | MEAN μ AFTER |
| SAMPLE | (m) | FAILURE | RUPTURE | RUPTURE |
| 60 Å Si/300 Å | 3683 | 97,709 | 0.102 | 0.396 |
| DLC | | | | |
| 3 × (20 Å Si/100 Å | 8104 | 214,971 | 0.047 | 0.384 |
| DLC) | | | | |

As shown in Table 1, the multi-layer protective coating has increased wear-through time and a significant reduction of the Coefficient of Friction (μ). As illustrated by these test results, the multi-layer protective coating according to the invention protects a feature more effectively than a single layer protective coating.

FIGS. 14-15 and the above description depict specific exemplary embodiments of the invention to teach those skilled in the art how to make and use the best mode of the invention. For the purpose of teaching inventive principles, some conventional aspects of the invention have been simplified or omitted. Those skilled in the art will appreciate variations from these embodiments that fall within the scope of the invention. Those skilled in the art will appreciate that the features described above can be combined in various ways to form multiple variations of the invention. As a result, the invention is not limited to the specific embodiments described, but only by the claims and their equivalents.

We claim:

1. a method of fabricating thin-film magnetic recording heads, the method comprising:
depositing a layer of feature material for a feature of a thin-film magnetic recording head; and
depositing at least two sets of alternating layers of an adhesion material and Diamond-Like Carbon (DLC) material to form a protective coating on the feature.

2. The method of claim 1 wherein depositing at least two sets of alternating layers comprises:
depositing a first layer of adhesion material on the feature;
depositing a first layer of DLC material on the first layer of adhesion material;
depositing a second layer of adhesion material on the first layer of DLC material;
depositing a second layer of DLC material on the second layer of adhesion material.

3. The method of claim 2 wherein depositing at least two alternating layers further comprises:
depositing a third layer of adhesion material on the second layer of DLC material; and
depositing a third layer of DLC material on the third layer of adhesion material.

4. The method of claim 2 wherein:
the ratio between the thickness of the first layer of DLC material and the thickness of the first layer of adhesion material is at least five to two.

5. The method of claim 1 wherein the adhesion material comprises Silicon (Si).

6. The method of claim 1 further comprising:
depositing at least one layer of another material on the protective coating; and
performing a Chemical/Mechanical Polishing (CMP) lift-off process on the at least one layer of another material down to the protective coating.

7. The method of claim 6 wherein the wherein the protective coating comprises a stop layer for the CMP lift-off process.

8. The method of claim 6 further comprising:
performing an etching process on the protective coating to remove the protective coating.

9. The method of claim 8 wherein the etching process comprises a reactive ion etching process.

10. The method of claim 1 wherein the feature comprises one of a read element or a write element.

11. The method of claim 1 wherein the thickness of the layers of the adhesion material are each about 20 Å and the thickness of the layers of the DLC material are each about 100 Å.

12. A method of fabricating thin-film magnetic recording heads, the method comprising:
(a) depositing a layer of feature material for a feature of a thin-film magnetic recording head;
(b) depositing an adhesion material;
(c) depositing a Diamond-Like Carbon (DLC) material on the adhesion material; and
(d) repeating (b) and (c) at least one time to form a protective coating on the feature.

13. The method of claim 12 wherein the adhesion material comprises Silicon (Si).

14. The method of claim 12 further comprising:
(e) performing a Chemical/Mechanical Polishing (CMP) lift-off process, wherein the protective coating acts as a stop layer for the CMP lift-off process.

15. The method of claim 14 further comprising:
(f) performing an etching process on the protective coating to remove the protective coating.

16. The method of claim 15 wherein the etching process comprises a reactive ion etching process.

17. The method of claim 12 wherein the feature comprises one of a read element or a write element.

18. The method of claim 12 wherein the thickness of the layers of the adhesion material are each about 20 Å and the thickness of the layers of the DLC material are each about 100 Å.

19. The method of claim 12 wherein:
the ratio between the thicknesses of the layers of DLC material and the thicknesses of the layers of adhesion material is at least five to two.

20. A method of fabricating thin-film magnetic recording heads, the method comprising:
depositing a layer of feature material for a feature of a thin-film magnetic recording head;
depositing a first layer of Silicon (Si) on the feature;
depositing a first layer of Diamond-Like Carbon (DLC) material on the first layer of Si;
depositing a second layer of Si on the first layer of DLC material; and
depositing a second layer of DLC material on the second layer of Si.

21. The method of claim 20 further comprising:
depositing a third layer of Si on the second layer of DLC material; and
depositing a third layer of DLC material on the third layer of Si.

22. The method of claim 20 wherein the feature comprises one of a read element or a write element.

23. The method of claim 20 wherein:
the ratio between the thickness of the first layer of DLC material and the thickness of the first layer of adhesion material is at least five to two.

24. The method of claim 20 wherein the thickness of the first layer of the adhesion material is about 20 Å and the thickness of the first layer of the DLC material is about 100 Å.

25. The method of claim 20 wherein the steps of depositing the first layer of Si and depositing the first layer of DLC material are performed at the same time.

26. The method of claim 25 wherein the steps of depositing the second layer of Si and depositing the second layer of DLC material are performed at the same time.

27. A method of fabricating thin-film magnetic recording heads, the method comprising:
depositing a layer of feature material for a feature of a thin-film magnetic recording head; and
depositing Silicon (Si) and Diamond-Like Carbon (DLC) material at the same time on the feature to form a protective layer on the feature.
